(19) United States
(12) Patent Application Publication
(10) Pub. No.: US 2009/0027563 A1
(43) Pub. Date: Jan. 29, 2009

(54) LOW NOISE AMPLIFIER

(76) Inventor: Cho-Chun Huang, HsinChu city (TW)

Correspondence Address: SINORICA, LLC, 528 FALLSGROVE DRIVE, ROCKVILLE, MD, 20850, US

(21) Appl. No.: 12/177,188

(22) Filed: Jul. 22, 2008

(30) Foreign Application Priority Data
Jul. 27, 2007 (TW) 096127413

(51) Int. Cl. H04N 5/50; H03G 3/30

(52) U.S. Cl. 348/731; 330/284; 348/E05.097

(57) ABSTRACT

The present invention provides a low noise amplifier, comprising a first active element having a first terminal, a second terminal and a third terminal, in which the first terminal is connected to an input terminal; a second active element having a first terminal, a second terminal and a third terminal, wherein the first terminal is connected to another input terminal; a first adjustable attenuation device which has a first terminal connected to the first terminal of the first active element and a second terminal connected to the second terminal of the second active element; and a second adjustable attenuation device which has a first terminal connected to the second terminal of the first active element and a second terminal connected to the first terminal of the second active element.

### BACKGROUND OF THE INVENTION

1. Field of the Invention

The present invention relates to a low noise amplifier, and more particularly to a low noise amplifier disposed in a tuner.

2. Description of the Related Art

With the advance of communication technique and compression technique, the global TV broadcast system has been developed from analog TV broadcast to digital TV broadcast. The revolution in digital TV broadcast will give significant development to all the related industries, for example, High Definition Television (HDTV) and Set Top Box (STB). Moreover, it will move toward a mobile application for receiving digital TV in the future so that it is no longer a dream to receive TV programs anytime and anywhere, and the tuner plays a critical role in the application of television set and set top box or future mobile receiving system.

Referring to FIG. 1A, a schematic diagram illustrating a conventional tuner with single conversion is depicted. The tuner can be a superheterodyne tuner. As shown in FIG. 1A, the tuner 100 comprises a filter 101, a low noise amplifier (LNA) 102, a mixer 106, a local oscillator 110 and a filter 112, and the filter 101 and the filter 112 can be SAW filters. The tuner 100 has an antenna (unlabeled) for receiving a RF signal (e.g. frequency range about 50-860 MHz) and passing the RF signal through the filter 101 to the low noise amplifier 102 for signal amplifying, and then down-converting the amplified signal through the mixer 106 and the local oscillator 110 to a range of Intermediate Frequency (IF) signal, for example, 36 MHz. Eventually, the filter 112 is provided to remove the unwanted channel thereof.

Next, referring to FIG. 1B, a schematic diagram illustrating a conventional tuner with dual conversion is depicted. As shown in FIG. 1B, the tuner 100 comprises a low noise amplifier 102, a mixer 106a, a local oscillator 110a, a band pass filter 104, a mixer 106b, a local oscillator 110b and a filter 112. The low noise amplifier 102 has one terminal connected to an antenna for amplifying the received RF signal. Next, the mixer 106a and the local oscillator 110a up-convert the amplified RF signal to a first IF signal, for example, 1 GHz, wherein the mixer 106a has one terminal connected to the output terminal of the low noise amplifier 102, and the local oscillator 110a is connected to another terminal of the mixer 106a for supplying a local oscillation frequency, for example, 1 GHz˜2 GHz. Next, the band pass filter 104 has an input terminal connected to the output terminal of the mixer 106b for outputting the IF signal with noise removal to another terminal. Next, the mixer 106b and the local oscillator 110b down-convert the first IF signal to the second IF signal, and eventually the filter 112 removes the unwanted channel thereof. Besides, the filter 112 can be a channel selection filter for removing other unwanted channel so as to complete the function of the tuner. Obviously, the tuner with dual conversion has the advantages of not requiring a multiplicity of filters for removing the mirror signal.

Next, referring to FIG. 1C, a schematic diagram illustrating a conventional tuner with single conversion is depicted. As shown in FIG. 1C, after the RF signal is amplified by the low noise amplifier 102, the amplified signal is divided into two parts, one of which is transmitted to a complex mixer 114 (so called Dual Quadrature Mixer), wherein the complex mixer 114 is composed of a plurality of mixers 106; meanwhile, a oscillation source 111 (LO) transmits a oscillation signal to the complex mixer 114 and obtains the I Path and Q Path Quadrature Low IF signal during signal mixing, wherein the oscillation source 111 and the phase separation circuit 115 (i.e. divided by two) generates a quadrature signal for quadrature phase. Then another IF multi-phase filter 113 converts the I Path and Q Path Quadrature Low IF signal into an I Path and Q Path Quadrature IF signal, and the channel selection filter (unlabeled) removes the unwanted channel from the I Path and Q Path Quadrature IF signal to complete the function of the tuner.

Next, referring to FIG. 1D, a schematic diagram illustrating a conventional tuner with dual conversion is depicted. As shown in FIG. 1D, after the RF signal is amplified by the low noise amplifier 102, the amplified signal is up-converted or down-converted by a first quadrature mixer (Quadrature Mixer1) and a first quadrature local oscillator (Quadrature LO1) to generate a co-phase signal (I_{IF1}) and a positive phase signal (Q_{IF1}), and then the complex mixer 122 and the second quadrature local oscillator 119 (Quadrature LO2) mix the co-phase signal (I_{IF1}) and the positive phase signal (Q_{IF1}) to generate an I_{IF1} and a Q_{IF1} of the quadrature Low IF signal. Next, the IF multi-phase filter 118 converts I_{IF1} and Q_{IF1} of the quadrature Low IF signal into an Low IF signal, and the channel selection filter (unlabeled) removes the unwanted channel from the Low IF signal to complete the function of the tuner.

In the above mentioned tuners 100, the low noise amplifier 102 is a critical component in order to have the input impedance match, the better gain and low noise of the received RF signal. In the prior arts, U.S. Pat. No. 5,384,501 and U.S. Pat. No. 7,081,796 disclose an attenuation element to improve the low noise amplifier. As shown in FIG. 2A, it is a diagram of one embodiment of the low noise amplifier disclosed in U.S. Pat. No. 7,081,796, the low noise amplifier uses four of NMOS transistors (324,326,334 and 336) as the amplifier 320, and uses inductors (322, 332) as a load, and it is characterized in that a NMOS transistor 340 is provided to connect with the output terminal of the amplifier 320, that is the drains of NMOS transistors 324 and 334, to form the attenuation element, and the gate of the NMOS transistor 340 is connected to a control voltage (V_{CNTL}), and properly control the control voltage (V_{CNTL}) to obtain the linear gain. Besides, as shown in FIG. 2B, it is a diagram of another prior art. Obviously, an attenuation element such as NMOS transistor 230 is connected to transistors 210 and 220 to form a low frequency amplifier. Similarly, it may obtain the linear gain by properly controlling the control voltage (V_{CNTL}).

However, when the gains are changed in FIG. 2A and FIG. 2B, for example to the maximum gain, it will cause the input impedance to change dramatically so that the low noise amplifier can not optimize the input impedance match and thus the return loss of the tuner is reduced, meanwhile, the noise suppression of the broadband signal is reduced. Therefore, the present invention is to provide a new circuit structure to make the impedance have fluctuation in small range when the low noise amplifier of the invention adjusts the gain so that the low noise amplifier and the tuner of the invention can maintain the impedance match in optimum situation.

### SUMMARY OF THE INVENTION

As mentioned above, in order to satisfy the industrial needs, one object of the present invention provides a low noise amplifier to ensure the better broadband impedance match.

Another object of the present invention is to provide a structure for a low noise amplifier so as to optimize the broadband noise and gain and gain flatness as well.

Accordingly, the present invention firstly provide a low noise amplifier which comprises a first active element having a first terminal, a second terminal and a third terminal, in which the first terminal is connected to an input terminal; a second active element having a first terminal, a second terminal and a third terminal, in which the first terminal is connected to another input terminal; a first adjustable attenuation device which has a first terminal connected to the first terminal of the first active element and a second terminal connected to the second terminal of the second active element; and a second adjustable attenuation device which has a first terminal connected to the second terminal of the first active element and a second terminal connected to the first terminal of the second active element.

Next, the present invention is to provide a tuner which comprises at least a filter, a low noise amplifier, a mixer, a local oscillator and a frequency selector, characterized in that the low noise amplifier comprises: a first active element having a first terminal, a second terminal and a third terminal, in which the first terminal is connected to an input terminal; a second active element having a first terminal, a second terminal and a third terminal, in which the first terminal is connected to another input terminal; a first adjustable attenuation device which has a first terminal connected to the first terminal of the first active element and a second terminal connected to the second terminal of the second active element; and a second adjustable attenuation device which has a first terminal connected to the second terminal of the first active element and a second terminal connected to the first terminal of the second active element.

Next, the present invention is to provide a tuner which comprises at least a low noise amplifier, a first mixer, a first local oscillator, a filter, a second mixer, a second local oscillator and a frequency selector, characterized in that: the low noise amplifier comprises: a first active element having a first terminal, a second terminal and a third terminal, wherein the first terminal is connected to an input terminal; a second active element having a first terminal, a second terminal and a third terminal, wherein the first terminal is connected to another input terminal; a first adjustable attenuation device which has a first terminal connected to the first terminal of the first active element and a second terminal connected to the second terminal of the second active element; and a second adjustable attenuation device which has a first terminal connected to the second terminal of the first active element and a second terminal connected to the first terminal of the second active element.

Next, the present invention is to provide a tuner which comprises a low noise amplifier, a first multi-phase filter, a dual quadrature mixer, a quadrature oscillator, a second multi-phase filter and a frequency selector, characterized in that the low noise amplifier comprises: a first active element having a first terminal, a second terminal and a third terminal, in which the first terminal is connected to an input terminal; a second active element having a first terminal, a second terminal and a third terminal, wherein the first terminal is connected to another input terminal; a first adjustable attenuation device which has a first terminal connected to the first terminal of the first active element and a second terminal connected to the second terminal of the second active element; and a second adjustable attenuation device which has a first terminal connected to the second terminal of the first active element and a second terminal connected to the first terminal of the second active element.

Next, the present invention is to provide a tuner which comprises a low noise amplifier, a quadrature mixer, a first quadrature oscillator, a dual quadrature mixer, a second quadrature oscillator, a multi-phase filter and a frequency selector, characterized in that the low noise amplifier comprises: a first active element having a first terminal, a second terminal and a third terminal, in which the first terminal is connected to an input terminal; a second active element having a first terminal, a second terminal and a third terminal, wherein the first terminal is connected to another input terminal; a first adjustable attenuation device which has a first terminal connected to the first terminal of the first active element and a second terminal connected to the second terminal of the second active element; and a second adjustable attenuation device which has a first terminal connected to the second terminal of the first active element and a second terminal connected to the first terminal of the second active element.

### BRIEF DESCRIPTION OF THE DRAWINGS

FIG. 1A˜FIG. 1D are schematic diagrams illustrating conventional tuners;

FIG. 2A˜FIG. 2B are schematic diagrams illustrating conventional low noise amplifiers of the present invention;

FIG. 3A˜FIG. 3B are schematic diagrams illustrating low noise amplifiers of the present invention;

FIG. 4A˜FIG. 4B are schematic diagrams illustrating another embodiment of the low noise amplifier of the present invention; and

FIG. 5 is a schematic diagram illustrating yet another embodiment of the low noise amplifier of the present invention.

### DETAILED DESCRIPTION OF THE INVENTION

Since the present invention discloses a low noise amplifier used in a broadband tuner, wherein the basic principles of the broadband tuner are well-known by those skilled in the art, the following description will omit the description of the principles. Moreover, the diagrams included in the following are not completely drawn according to the real size and are only used to demonstrate features related to the present invention.

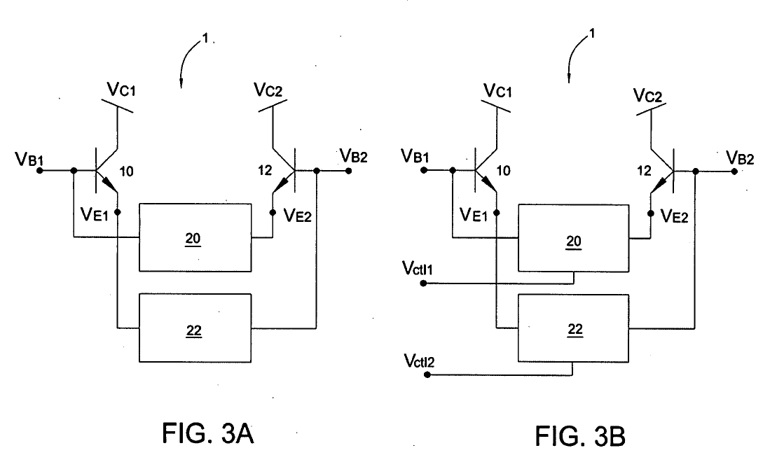

Firstly, referring to FIG. 3A, a schematic circuit diagram illustrating a low noise amplifier of the present invention is depicted. As shown in FIG. 3A, the low noise amplifier 1 comprises at least a first active element 10, a second active element 12 and a plurality of adjustable attenuation devices 20, 22. Each active element of the low noise amplifier 1 comprises a first terminal, a second terminal and a third terminal. In this embodiment, these active elements are Bipolar Junction Transistor (BJT) in which the first terminal is a base terminal, the second terminal is an emitter terminal and the third terminal is a collector terminal. Besides, the adjustable attenuation devices 20, 22 can be an element with two terminals such as resistors, inductors, capacitors, diodes or any combination of thereof; meanwhile, the adjustable attenuation device can be an element with three terminals such as Bipolar Junction Transistor (BJT), Field Effect Transistor (FET), Metal Oxide Semiconductor Field Effect Transistor (MOSFET), Complementary Metal Oxide Semiconductor (CMOS) or the like.

Referring back to FIG. 3A, the base terminal of the first active element 10 and the base terminal of the second active element 12 are connected to the input terminals, respectively, for receiving the feed through broadband RF signal from the antenna of the tuner, and the first terminal of the first adjustable attenuation device 20 is connected to the base terminal of the first active element 10 and another terminal thereof is connected to the emitter terminal of the second active element 12 when the first adjustable attenuation device 20 is a dual-terminal element; besides, the first terminal of the second adjustable attenuation device 20 is connected to the base terminal of the second active element 12 and another terminal thereof is connected to the emitter terminal of the first active element 10 when the second adjustable attenuation device 20 is a dual-terminal element. Obviously, when the voltage (V_{B1}) at the base terminal of the first active element 10 and the voltage (V_{E2}) at the emitter terminal of the second active element 12 are adjusted or changed, the impedance of the adjustable attenuation device 20 is changed; and when the voltage (V_{E1}) at the emitter terminal of the first active element 10 and the voltage (V_{B2}) at the base terminal of the second active element 12 are adjusted or changed, the impedance of the adjustable attenuation device 22 is changed. Thus, when the gain of the first active element 10 and the gain of the second active element 12 of the present invention are adjusted, for example, a power managing device for adjusting the gain of the low noise amplifier, the first adjustable attenuation device 20 is connected to the second adjustable attenuation device 22 so as to make the input impedance of the low noise amplifier 1 varied in a small range, for example, the input impedance varied in the range of 50±2Ω. Thus, the low noise amplifier and tuner of the present invention can be maintained in the optimized state of impedance match. Surely, the input signal may selectively be sent to an amplifying circuit (unlabeled) such as an Auto Gain Control circuit (AGC) before it is sent to the low noise amplifier 1 via the antenna of the tuner.

Besides, in order to adjust the input impedance match, the adjustable attenuation devices 20,22 in this embodiment may be selected from the elements with adjusting feature such as variable resistor, variable capacitor, variable inductor. Besides, the third terminal of the first active element 10 and the third terminal of the second active element 12, for example, collector terminal, are connected to the dual-terminal element (unlabeled) for the load of the low noise amplifier 1, wherein the dual-terminal element can be resistor, inductor, capacitor, diode or any combination of thereof.

Next, Referring to FIG. 3B, a schematic circuit diagram illustrating another embodiment of the low noise amplifier of the present invention is depicted. The base terminal of the first active element 10 of the low noise amplifier 1 and the base terminal of the second active element 12 of the low noise amplifier 1 are connected to the input terminals, respectively, for receiving the feed through broadband RF signal from the antenna of the tuner. When the first adjustable attenuation device 20 is a tri-terminal element (e.g. a BJT), the third terminal (e.g. collector) thereof is connected to the base terminal of the first active element 10, the second terminal (e.g. emitter) thereof is connected to the emitter terminal of the second active element 12, and the first terminal (e.g. base) thereof s connected to the voltage control terminal of an adjustable voltage (V_{ctl1}). Besides, When the second adjustable attenuation device 22 is also a tri-terminal element (e.g. a BJT), the third terminal (e.g. collector) thereof is connected to the base terminal of the second active element 12, the second terminal (e.g. emitter) thereof is connected to the emitter terminal of the first active element 10, and the first terminal (e.g. base) thereof is connected to the voltage control terminal of an adjustable voltage (V_{ctl2}). Obviously, when the voltage (V_{B1}) at the base terminal of the first active element 10 and the voltage (V_{E2}) at the emitter terminal of the second active element 12 are adjusted to a predetermined value, the impedance of the adjustable attenuation device 20 is changed through adjusting the voltage (V_{ctl1}) at the voltage control terminal of the adjustable attenuation device 20; similarly, when the voltage (V_{E1}) at the emitter terminal of the first active element 10 and the voltage (V_{B2}) at the base terminal of the second active element 12 are adjusted or changed to a predetermined value, the impedance of the adjustable attenuation device 22 is changed through adjusting the voltage (V_{ctl1}) at the voltage control terminal of the adjustable attenuation device 22. Thus, when the input impedance of the low noise amplifier 1 is varied in a small range, for example, 75±5Ω, the first adjustable attenuation device 20 is connected to the second adjustable attenuation device 22. Thus, the low noise amplifier and tuner of the present invention can be maintained in an optimized state of impedance match. Surely, the input signal may be selectively sent to an amplifying circuit (unlabeled) such as an Auto Gain Control circuit (AGC) before it is sent to the low noise amplifier 1 via the antenna of the tuner.

Besides, in order to adjust the input impedance match, the adjustable attenuation devices 20 and 22 in this embodiment may be selected from the elements consisting of Bipolar Junction Transistor (BJT), Field Effect Transistor (FET), Metal Oxide Semiconductor Field Effect Transistor (MOSFET), Complementary Metal Oxide Semiconductor (CMOS) or the like elements. Meanwhile, in a preferable embodiment, the voltages at the voltage control terminal V_{ctl1}, V_{ctl2} can be set to be zero. The third terminals (e.g. collector) of the first active element 10 and the second active element 12 can be further connected to the dual-terminal element (unlabeled) for the load of the low noise amplifier 1, wherein the dual-terminal element can be resistor, inductor, capacitor, diode or any combination of thereof.

Besides, the first adjustable attenuation device 20 and the second adjustable attenuation device 22 of the present invention shown in FIG. 3A and FIG. 3B can be formed by selecting a plurality of elements connected to one another in parallel, that is, the first adjustable attenuation device 20 and the second adjustable attenuation device 22 can be formed of a plurality of adjustable attenuation devices connected to one another in parallel, respectively.

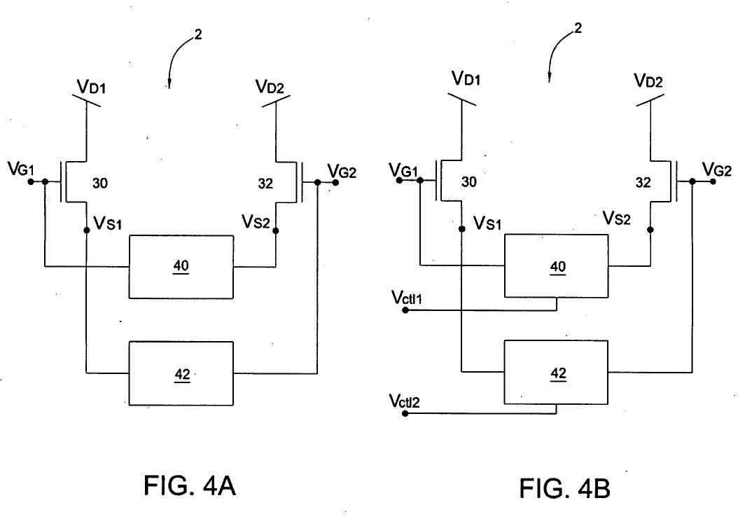

Next, referring to FIG. 4A, a schematic circuit diagram illustrating yet another embodiment of the low noise amplifier of the present invention is depicted. As shown in FIG. 4A, the low noise amplifier 2 comprises a first active element 30, a second active element 32 and a plurality of adjustable attenuation devices 40, 42, in which the adjustable attenuation devices 40,42 can be selected from Field Effect Transistor (FET), Metal Oxide Semiconductor Field Effect Transistor (MOSFET), Complementary Metal Oxide Semiconductor (CMOS) or the like. Thus the active element has a first terminal as a gate terminal, a second terminal as a source terminal and a third terminal as a drain terminal. Besides, the adjustable attenuation device can be a dual-terminal element such as resistor, inductor, capacitor, diode or any combination of thereof; meanwhile, the adjustable attenuation device can also be a tri-terminal element such as Bipolar Junction Transistor, Field Effect Transistor, Metal Oxide Semiconductor Field Effect Transistor or Complementary Metal Oxide Semiconductor.

Obviously, the structure of circuit connection in the present embodiment is the same as those in FIG. 3A and FIG. 3B, the only difference is that is each active element of BJT replaced with FET, MOSFET or CMOS, and NMOS is used as an active element in the present embodiment.

As shown in FIG. 4A, the gate terminal of the first active element 30 and the gate terminal of the second active element 32 are connected to the input terminal for receiving the broadband RF signal from the antenna of the tuner, and when the first adjustable attenuation device 40 is a dual-terminal element, the first terminal thereof is connected to the gate terminal (V_{G1}) of the first active element 30 and another terminal thereof is connected to the source terminal (V_{S2}) of the second active element 32; besides, when the second adjustable attenuation device 42 is also a dual-terminal element, the first terminal thereof is connected to the gate terminal (V_{G2}) of the second active element 32 and another terminal thereof is connected to the source terminal (V_{S1}) of the first active element 30. Obviously, when the gain of the low noise amplifier 2 of the present invention is adjusted, for example, a power managing device operatively for adjusting the gain of the low noise amplifier, the first adjustable attenuation device 40 is connected to the second adjustable attenuation device 42 so as to make the input impedance of the low noise amplifier 2 varied in a small range, for example, the input impedance varied in the range of 50±2Ω. Thus, the low noise amplifier and tuner of the present invention can be maintained in the optimized state of impedance match. Surely, the input signal may be selectively sent to an amplifying circuit (unlabeled) such as an Auto Gain Control circuit (AGC) before it is sent to the low noise amplifier 2 via the antenna of the tuner.

Besides, in order to adjust the input impedance match, the adjustable attenuation devices 40 and 42 in this embodiment may be selected from the elements with adjusting feature such as variable resistor, variable capacitor, or variable inductor. The third terminal of the first active element 30 and the third terminal of the second active element 32, for example, collector terminal, are further connected to the dual-terminal element (unlabeled) for the load of the low noise amplifier 2, wherein the dual-terminal element can be resistor, inductor, capacitor, diode or any combination of thereof.

Next, referring to FIG. 4B, a schematic circuit diagram illustrating another embodiment of the low noise amplifier of the present invention. The base terminal of the first active element 30 of the low noise amplifier 2 and the base terminal of the second active element 32 of the low noise amplifier 2 are connected to the input terminals, respectively, for receiving the feedthrough broadband RF signal from the antenna of the tuner. When the first adjustable attenuation device 40 is a tri-terminal element (e.g. a NMOS), the third terminal (e.g. Drain) thereof is connected to the base terminal of the first active element 30, the second terminal (e.g. Source) thereof is connected to the emitter terminal of the second active element 32, and the first terminal (e.g. Gate) thereof s connected to the voltage control terminal of an adjustable voltage (V_{ctl1}). Besides, When the second adjustable attenuation device 42 is also a tri-terminal element (e.g. a NMOS), the third terminal (e.g. Drain) thereof is connected to the gate terminal (V_{G2}) of the second active element 32, the second terminal (e.g. source) thereof is connected to the source terminal (V_{S1}) of the first active element 30, and the first terminal (e.g. gate) thereof is connected to the voltage control terminal of an adjustable voltage (V_{ctl2}). Obviously, when the voltage (V_{G1}) at the gate terminal of the first active element 30 and the voltage (V_{S2}) at the source terminal of the second active element 32 are adjusted to a predetermined value while the voltage (V_{ctl1}) at the voltage control terminal of the first adjustable attenuation device 40 is adjusted to a proper value, the impedance of the adjustable attenuation device 40 is changed; similarly, when the voltage (V_{S1}) at the source terminal of the first active element 30 and the voltage (V_{G2}) at the gate terminal of the second active element 32 are adjusted or changed while the voltage (V_{ctl2}) at the voltage control terminal of the second adjustable attenuation device 42 is adjusted to a proper value, the impedance of the second adjustable attenuation device 42 is changed. Therefore, through connecting with the adjustable attenuation device 40 or the second adjustable attenuation device 42, the input impedance of the low noise amplifier 2 is varied in a small range, for example, 75±5Ω. Thus, the low noise amplifier and tuner of the present invention can be maintained in an optimized state of impedance match. Surely, the input signal may be selectively sent to an amplifying circuit (unlabeled) such as an Auto Gain Control circuit (AGC) before it is sent to the low noise amplifier 2 via the antenna of the tuner.

Besides, in order to adjust the input impedance match, the adjustable attenuation devices 40 and 42 in this embodiment may be selected from the elements consisting of Bipolar Junction Transistor, Field Effect Transistor, Metal Oxide Semiconductor Field Effect Transistor, Complementary Metal Oxide Semiconductor or the like elements. Meanwhile, in a preferable embodiment, the voltages at the voltage control terminal V_{ctl1},V_{ctl2} can be set to be zero. The third terminals (e.g. drain) of the first active element 30 and the second active element 32 can be connected to the dual-terminal element (unlabeled) for the load of the low noise amplifier 2, wherein the dual-terminal element can be resistor, inductor, capacitor, diode or any combination of thereof.

Besides, the first adjustable attenuation device 40 and the second adjustable attenuation device 42 of the present invention shown in FIG. 4A and FIG. 4B can be formed by selecting a plurality of elements connected to one another in parallel, that is, the first adjustable attenuation device 40 and the second adjustable attenuation device 42 can be formed of a plurality of adjustable attenuation device connected to one another in parallel, respectively.

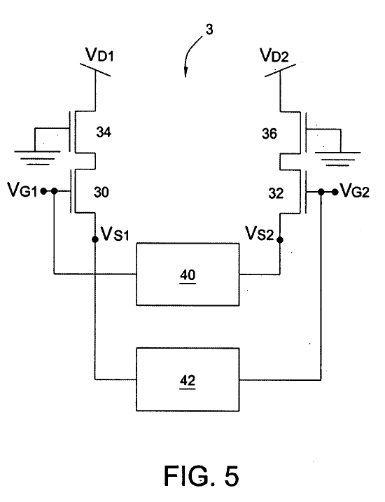

Next, referring to FIG. 5, a schematic circuit diagram illustrating another embodiment of the low noise amplifier of the present invention. As shown in FIG. 5, the low noise amplifier 3 comprises a first active element 30, a second active element 32, a third active element 34, a fourth active element 36 and a plurality of adjustable attenuation devices 40, 42, in which each of the active elements can be selected from Field Effect Transistor (FET), Metal Oxide Semiconductor Field Effect Transistor (MOSFET), Complementary Metal Oxide Semiconductor (CMOS) or the like. Thus the active element has a first terminal as a gate terminal, a second terminal as a source terminal and a third terminal as a drain terminal. Besides, each of the adjustable attenuation devices can be a dual-terminal element such as resistor, inductor, capacitor, diode or any combination of thereof; meanwhile, each of the adjustable attenuation devices can also be a tri-terminal element such as Bipolar Junction Transistor, Field Effect Transistor, Metal Oxide Semiconductor Field Effect Transistor or Complementary Metal Oxide Semiconductor.

Obviously, the structure of circuit connection in the present embodiment is identical to those in FIG. 4A and FIG. 4B, except that the active elements 30 and 32 in FIG. 4A and FIG. 4B are connected to an active element 34 and 36, respectively, in which the third terminal (drain) of the active element 30 is connected to the second terminal (source) of the active element 34. Besides, the third terminal (drain) of the active element 34 is connected to a load element, and the first terminal (gate) of the active element 34 is connected to a ground terminal. Similarly, the third terminal (drain) of the active element 32 is connected to the second terminal (source) of the active element 36, the third terminal (drain) of the active element 36 is connected to a load element, and the first terminal (gate) of the active element 36 is connected to a ground terminal. The purpose of adding the active elements 34 and 36 to the structure is to further increase the output impedance of the low noise amplifier.

Similarly, in the embodiments in FIG. 3A and FIG. 3B, an active element can be connected to the active element 10, 12. Surely, the added active element can be selected from Bipolar Junction Transistor, Field Effect Transistor, Metal Oxide Semiconductor Field Effect Transistor or Complementary Metal Oxide Semiconductor. Since the structure of circuit connection and operation process for adding the active element(s) is identical to the above mentioned embodiments, there is no more explanation herein.

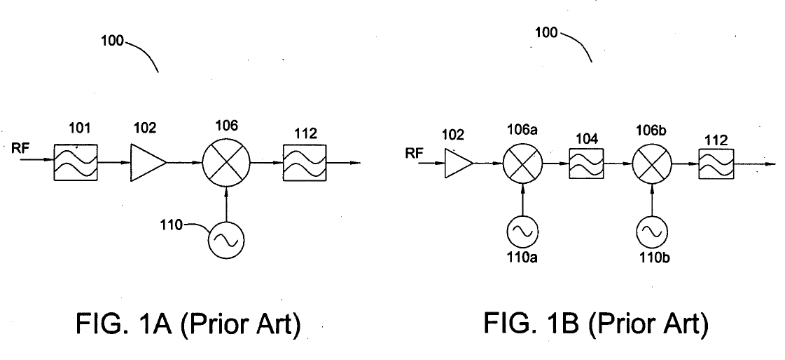

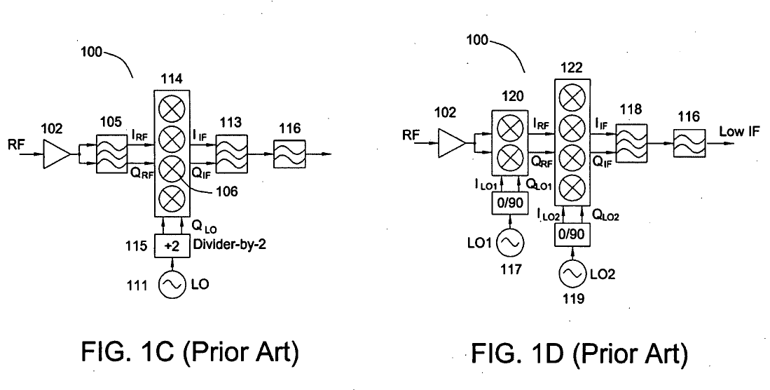

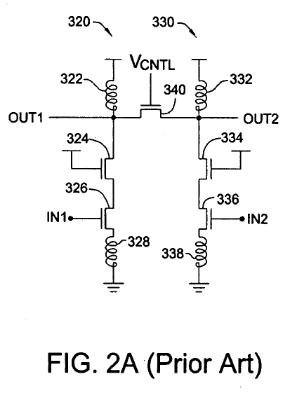

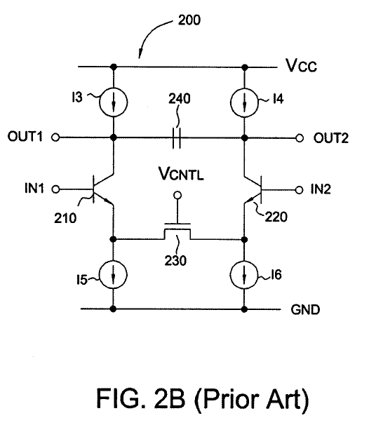

Besides, it is noted that the circuit of the above mentioned low noise amplifier can be formed on a wafer due to the advance of the semiconductor manufacturing such that the tuner can be fulfilled in a type of chip. Meanwhile, the low noise amplifier of the present invention can be substituted for the low noise amplifier in the tuner 100 (prior arts from FIG. 1A to FIG. 1D). The tuner provided with the low noise amplifier of the present invention may have better impedance match and improve noise suppression of circuit as well by means of proper design for bias voltage.

The above mentioned preferred embodiments of the present invention are not meant to limit the scope of the present invention. The description of the present invention should be understood by those skilled in the art. Moreover, any changes or modifications or the equivalent thereof that can be made without departing from spirit of the present invention should be protected by the following claims.

What is claimed is:

1. A low noise amplifier, comprising:
a first active element having a first terminal, a second terminal and a third terminal, wherein the first terminal is connected to an input terminal;
a second active element having a first terminal, a second terminal and a third terminal, wherein the first terminal is connected to another input terminal;
a first adjustable attenuation device which has a first terminal connected to the first terminal of the first active element and a second terminal connected to the second terminal of the second active element; and
a second adjustable attenuation device which has a first terminal connected to the second terminal of the first active element and a second terminal connected to the first terminal of the second active element.

2. The low noise amplifier according to claim 1, wherein the first active element and the second active element are selected from the group consisting of Bipolar Junction Transistor (BJT), Field Effect Transistor (FET), Metal Oxide Semiconductor (MOS) and Complementary Metal Oxide Semiconductor (CMOS).

3. The low noise amplifier according to claim 1, wherein the first adjustable attenuation device and the second adjustable attenuation device are selected from the group consisting of resistor, inductor, capacitor, diode and any combination thereof.

4. The low noise amplifier according to claim 1, wherein the first adjustable attenuation device and the second adjustable attenuation device are tri-terminal active elements, respectively.

5. The low noise amplifier according to claim 4, wherein the tri-terminal active element is selected from the group consisting of Bipolar Junction Transistor (BJT), Field Effect Transistor (FET), and Metal Oxide Semiconductor (MOS).

6. The low noise amplifier according to claim 4, wherein the tri-terminal active element has a third terminal connected to the first terminal of the first active element, a second terminal connected to the second terminal of the second active element, and a first terminal connected to a voltage control terminal (V_{ctl}).

7. The low noise amplifier according to claim 6, wherein the voltage control terminal (V_{ctl}) has a voltage set to be zero.

8. The low noise amplifier according to claim 1, further comprising a plurality of adjustable attenuation devices connected to one another in parallel to form the first adjustable attenuation device and a plurality of adjustable attenuation devices connected to one another in parallel to form the second adjustable attenuation device.

9. The low noise amplifier according to claim 1, further comprising at least a load element connected to the third terminal of the first active element and the third terminal of the second active element, respectively.

10. The low noise amplifier according to claim 9, wherein the load element is selected from the group consisting of resistor, inductor, capacitor, diode or any combination thereof.

11. The low noise amplifier according to claim 1, further comprising:
a third active element having a second terminal connected to the third terminal of the first active element and a third terminal connected to a load element; and
a fourth active element having a second terminal connected to the third terminal of the second active element and a third terminal connected to a load element.

12. A tuner comprising at least a filter, a low noise amplifier, a mixer, a local oscillator and a frequency selector, characterized in that:
the low noise amplifier comprises:
a first active element having a first terminal, a second terminal and a third terminal, wherein the first terminal is connected to an input terminal;
a second active element having a first terminal, a second terminal and a third terminal, wherein the first terminal is connected to another input terminal;
a first adjustable attenuation device which has a first terminal connected to the first terminal of the first active element and a second terminal connected to the second terminal of the second active element; and
a second adjustable attenuation device which has a first terminal connected to the second terminal of the first active element and a second terminal connected to the first terminal of the second active element.

13. The low noise amplifier according to claim 12, wherein the first active element and the second active element are selected from the group consisting of Bipolar Junction Transistor (BJT), Field Effect Transistor (FET), Metal Oxide Semiconductor (MOS) and Complementary Metal Oxide Semiconductor (CMOS).

14. The low noise amplifier according to claim 12, wherein the first adjustable attenuation device and the second adjustable attenuation device are selected from the group consisting of resistor, inductor, capacitor, diode and any combination thereof.

15. The low noise amplifier according to claim 12, wherein the first adjustable attenuation device and the second adjustable attenuation device are tri-terminal active elements, respectively.

16. The low noise amplifier according to claim 12, wherein the tri-terminal active element is selected from the group consisting of Bipolar Junction Transistor (BJT), Field Effect Transistor (FET), and Metal Oxide Semiconductor (MOS).

17. The low noise amplifier according to claim 15, wherein the tri-terminal active element has a second terminal connected to the first terminal of the first active element, a third terminal connected to the second terminal of the second active element, and a first terminal connected to a voltage control terminal (V_{ctl}).

18. The low noise amplifier according to claim 17, wherein the voltage control terminal (V_{ctl}) has a voltage set to be zero.

19. The low noise amplifier according to claim 12, further comprising a plurality of adjustable attenuation devices connected to one another in parallel to form the first adjustable attenuation device and a plurality of adjustable attenuation devices connected to one another in parallel to form the second adjustable attenuation device.

20. The low noise amplifier according to claim 12, further comprising at least a load element connected to the third terminal of the first active element and the third terminal of the second active element, respectively.

21. The low noise amplifier according to claim 20, wherein the load element is selected from the group consisting of resistor, inductor, capacitor, diode or any combination thereof.

22. The low noise amplifier according to claim 12, further comprising:
a third active element having a second terminal connected to the third terminal of the first active element and a third terminal connected to a load element; and
a fourth active element having a second terminal connected to the third terminal of the second active element and a third terminal connected to a load element.

23. The low noise amplifier according to claim 12, wherein the frequency selector is a surface audio wave filter (SAW).

24. A tuner comprising at least a low noise amplifier, a first mixer, a first local oscillator, a filter, a second mixer, a second local oscillator and a frequency selector, characterized in that:
the low noise amplifier comprises:
a first active element having a first terminal, a second terminal and a third terminal, wherein the first terminal is connected to an input terminal;
a second active element having a first terminal, a second terminal and a third terminal, wherein the first terminal is connected to another input terminal;
a first adjustable attenuation device which has a first terminal connected to the first terminal of the first active element and a second terminal connected to the second terminal of the second active element; and
a second adjustable attenuation device which has a first terminal connected to the second terminal of the first active element and a second terminal connected to the first terminal of the second active element.

25. A tuner comprising at least a low noise amplifier, a first multi-phase filter, a dual quadrature mixer, a quadrature oscillator, a second multi-phase filter and a frequency selector, characterized in that:
the low noise amplifier comprises:
a first active element having a first terminal, a second terminal and a third terminal, wherein the first terminal is connected to an input terminal;
a second active element having a first terminal, a second terminal and a third terminal, wherein the first terminal is connected to another input terminal;
a first adjustable attenuation device which has a first terminal connected to the first terminal of the first active element and a second terminal connected to the second terminal of the second active element; and
a second adjustable attenuation device which has a first terminal connected to the second terminal of the first active element and a second terminal connected to the first terminal of the second active element.

26. A tuner comprising at least a low noise amplifier, a quadrature mixer, a first quadrature oscillator, a dual quadrature mixer, a second quadrature oscillator, a multi-phase filter and a frequency selector, characterized in that:
the low noise amplifier comprises:
a first active element having a first terminal, a second terminal and a third terminal, wherein the first terminal is connected to an input terminal;
a second active element having a first terminal, a second terminal and a third terminal, wherein the first terminal is connected to another input terminal;
a first adjustable attenuation device which has a first terminal connected to the first terminal of the first active element and a second terminal connected to the second terminal of the second active element; and
a second adjustable attenuation device which has a first terminal connected to the second terminal of the first active element and a second terminal connected to the first terminal of the second active element.
